(19) United States
(12) Patent Application Publication
(10) Pub. No.: US 2026/0024719 A1
(43) Pub. Date: Jan. 22, 2026

(54) Charged Particle Beam Apparatus and Charged Particle Gun

(71) Applicant: Hitachi High-Tech Corporation, Tokyo (JP)

(72) Inventors: Kensuke TOKUMURA, Tokyo (JP); Masahiro FUKUTA, Tokyo (JP); Masayuki FUKUMOTO, Tokyo (JP)

(21) Appl. No.: 19/272,609

(22) Filed: Jul. 17, 2025

(30) Foreign Application Priority Data
Jul. 18, 2024 (JP) 2024-114464

(51) Int. Cl. H01J 37/317; H01J 37/06; H01J 37/10; H01J 37/20

(52) U.S. Cl. CPC H01J 37/317; H01J 37/06; H01J 37/10; H01J 37/20

(57) ABSTRACT

A charged particle beam apparatus includes: a charged particle source support member that directly or indirectly supports a charged particle source; and a moving mechanism configured to move the charged particle source support member. The moving mechanism has a first function of, with a travel direction of a charged particle emitted from the charged particle source defined as a Z direction, a direction perpendicular to the Z direction defined as an X direction, and a direction perpendicular to the Z direction and the X direction defined as a Y direction, moving the charged particle source support member in the X direction, the Y direction, and the Z direction, and a second function of moving the charged particle source support member in the Z direction from an outside of a vacuum chamber, separately from the first function.

### BACKGROUND OF THE INVENTION

### 1. Field of the Invention

The present invention relates to a charged particle beam apparatus and a charged particle gun.

### 2. Description of Related Art

As a background art of the present technical field, PTL 1 and PTL 2 below discloses a technique of performing position adjustment of a charged particle source which is an for example. The description of these electron source, literatures is included as a part of the specification of the present application.

### CITATION LIST

### Patent Literature

PTL 1: JPH10-255711A
PTL 2: JP2007-19045A

### SUMMARY OF THE INVENTION

In the above-described technique, there is a demand for achieving more appropriate position adjustment of the charged particle source.

The invention has been made in view of the above circumstances, and an object thereof is to provide a charged particle beam apparatus and a charged particle gun capable of achieving appropriate position adjustment of a charged particle source.

In order to solve the above problems, the charged particle beam apparatus according to the invention includes: a charged particle gun configured to perform irradiation with a charged particle beam; and a focusing lens. The focusing lens focuses charged particles by an electric field or a magnetic field and irradiates a sample with the focused charged particles, the charged particle gun includes a charged particle source configured to emit the charged particles, a vacuum chamber that surrounds the charged particle source, a charged particle source support member that directly or indirectly supports the charged particle source, and a moving mechanism configured to move the charged particle source support member, and the moving mechanism has a first function of, with a travel direction of the charged particles emitted from the charged particle source defined as a Z direction, a direction perpendicular to the Z direction defined as an X direction, and a direction perpendicular to the Z direction and the X direction defined as a Y direction, moving the charged particle source support member in the X direction, the Y direction, and the Z direction, and a second function of moving the charged particle source support member in the Z direction from an outside of the vacuum chamber, separately from the first function.

According to the invention, it is possible to achieve appropriate position adjustment of the charged particle source.

### BRIEF DESCRIPTION OF THE DRAWINGS

FIG. 1 is a schematic diagram of an electron gun according to a first embodiment;

FIG. 2 is a schematic diagram of an electron gun according to a second embodiment;

FIG. 3 is a schematic perspective view of main parts of an electron gun according to a third embodiment;

FIG. 4 is a schematic cross-sectional view of main parts of an electron gun according to a fourth embodiment;

FIG. 5 is a schematic diagram of an electron gun according to a fifth embodiment;

FIG. 6 is a schematic diagram of an electron gun according to a sixth embodiment;

FIG. 7 is a schematic diagram of a charged particle beam apparatus according to a seventh embodiment;

FIG. 8 is a schematic diagram of a charged particle beam apparatus according to an eighth embodiment;

FIG. 9 is a schematic diagram of a charged particle beam apparatus according to a ninth embodiment; and

FIG. 10 is a block diagram of a computer.

### DESCRIPTION OF EMBODIMENTS

### Overview of Embodiments

A charged particle beam apparatus includes a charged particle gun that emits a charged particle beam. For example, a scanning electron microscope (SEM) includes an electron gun. Further, the charged particle gun has a charged particle source, and a charged particle beam emitted from the charged particle source is emitted from the charged particle gun. In a case of the SEM, an electron beam is emitted from an electron source provided in an electron gun and emitted from the electron gun. As the electron source, for example, a tungsten crystal is used.

In recent years, in order to achieve high throughput by a large current probe, many short focus type or magnetic field superposition type charged particle guns in which a distance between a charged particle source and a focusing lens is short have been developed. In a charged particle beam apparatus, it is important to provide a moving mechanism for adjusting a position of the charged particle source. This is because the position of the charged particle source may deviate from a design position due to an assembly tolerance or the like. In a case of the SEM, when the position of the electron source is shifted, an aperture angle and an aberration coefficient on a sample are changed from design values, and it is considered that target resolution cannot be obtained.

Therefore, it is desirable that the charged particle beam apparatus includes some charged particle source moving mechanism that allows the charged particle source to be moved. Hereinafter, in the present specification, a travel direction of a charged particle beam emitted from a charged particle source is referred to as a Z direction, and first and second directions perpendicular to the Z direction are referred to as an X direction and a Y direction, respectively. When the technique of PTL 1 described above is applied, it is considered that it is possible to implement an ultra-high vacuum surface observation apparatus including a mechanism in a vacuum chamber that uses a piezoelectric element capable of moving the charged particle source in each of XYZ directions. When the technique of PTL 2 is applied, it is considered that it is possible to implement an electron beam application device including a mechanism capable of moving a charged particle source in each of X and Y directions outside a vacuum chamber.

However, in a structure in which an XYZ moving mechanism using the piezoelectric element is provided in the vacuum chamber as in the technique to which PTL 1 is applied, there is a problem in that a baking temperature of a charged particle gun is restricted. In the charged particle gun, in order to allow a charged particle beam to pass therethrough, an inside is generally set to a high vacuum to an ultra-high vacuum. Therefore, baking processing of the charged particle gun is generally performed. If the piezoelectric element is provided in the vacuum chamber, an upper limit of the temperature at which baking can be performed is lowered, and it is considered that degassing of the charged particle gun cannot be sufficiently performed and an ultimate vacuum degree is deteriorated. Instead of the piezoelectric element, the XYZ moving mechanism using a motor or the like may be provided in the vacuum chamber, but in any case, similarly, there is a problem that the temperature at which baking can be performed is lowered.

In a structure in which a mechanism for moving a position of the charged particle source is provided outside the vacuum chamber as in the technique to which PTL 2 is applied, there is a problem that positioning accuracy is deteriorated due to an air pressure difference. In particular, in order to move the position of the charged particle source in the Z direction from the outside of the vacuum chamber, it is necessary to provide a member that supports the charged particle source while separating an inside and outside of the vacuum chamber and to provide a mechanism that moves the member in the Z direction. However, since there is an air pressure difference between the inside and outside of the vacuum chamber, in order to move the member in the Z direction, it is necessary to move the member with a force exceeding a force due to an atmospheric pressure. It is difficult to precisely move the position of the charged particle source in the Z direction under such conditions.

Meanwhile, in the short focus type or magnetic field superposition type charged particle gun, sensitivity of positional deviation of the charged particle source with respect to a focusing lens is higher than that of the charged particle gun in the related art. Therefore, there is a demand for setting XYZ positions of the charged particle source with higher accuracy than in the related art. In particular, regarding the Z position, since a distance between the charged particle source and the focusing lens is reduced, longitudinal magnification of an optical system becomes large, and it is important to perform positioning with higher accuracy. When the technique of PTL 2 is applied, it is considered that the charged particle source can be moved in the XY directions from an outside of the charged particle gun. However, in PTL 2, a method of moving the charged particle source in the Z direction is not particularly described in detail.

In order to solve the above-described problem, a charged particle gun and a charged particle beam apparatus provided by the present disclosure include a moving mechanism that moves a charged particle source support member. The moving mechanism has a first function of moving the charged particle source support member in XYZ directions, and separately from the first function, a second function of moving the charged particle source support member from an outside of the vacuum chamber.

Further, the charged particle beam apparatus provided by the present disclosure includes: a drive unit configured to adjust a position of the charged particle source support member; a detector; and a user interface device, and is configured to adjust a position of the charged particle source support member such that a parameter displayed on the user interface device is optimized.

According to the embodiment of the present disclosure, the second function bears a force due to an air pressure difference, and the first function, which is free from an atmospheric pressure, allows the position of the charged particle source support member to be adjusted in three directions, that is, XYZ. In a configuration according to the present disclosure, since it is not necessary to provide a mechanism such as a piezoelectric element or a motor inside the vacuum chamber, a baking temperature of a charged particle gun can be set to a high temperature to sufficiently perform degassing.

Further, according to the embodiment of the present disclosure, it is possible to move the charged particle source in the three directions, that is, XYZ, so that one or more parameters displayed on the user interface device are optimized.

Hereinafter, embodiments of the invention will be described with reference to the drawings. In the drawings described below, members having the same or similar functions have the same reference signs and description thereof may not be repeated.

In the following embodiments, as a charged particle beam apparatus and a charged particle gun, those mainly applied to a scanning electron microscope (SEM) and an electron gun will be exemplified. However, the following embodiments are not construed as being limited thereto, and can be applied to, for example, an ion beam apparatus or an ion gun.

### First Embodiment

FIG. 1 is a schematic diagram of an electron gun 100 according to a first embodiment. The electron gun 100 according to the present embodiment is mainly applied to an SEM as an example of a charged particle beam apparatus. At this time, the charged particle gun in the charged particle beam apparatus in the example described below is an electron gun, and similarly, the charged particle beam and a charged particle source are an electron beam and an electron source, respectively.

In FIG. 1, the electron gun 100 (charged particle gun, charged particle beam apparatus) includes a vacuum chamber 101, an electron source 103 (charged particle source), a condenser coil 105 (focusing lens), an electron source support member 106 (charged particle source support member), and a moving mechanism 107. A high vacuum space 102 is formed inside the vacuum chamber 101. The electron source 103 and the condenser coil 105 are provided inside the vacuum chamber 101. The electron source 103 emits an electron beam 104 (charged particle beam). The condenser coil 105 is a coil that focuses the electron beam 104, which is a charged particle beam. That is, a magnetic field is generated by supplying a current to the condenser coil 105, and the electron beam 104 is focused by the magnetic field.

The electron beam 104 does not necessarily have to be focused by a magnetic field, and may be focused by an electric field. In this case, two or more electrodes (not illustrated) having a potential difference may be disposed instead of the condenser coil 105. Further, it is not necessary to provide a member (the condenser coil 105 or the above-described electrode) for focusing the electron beam inside the electron gun 100, and the member may be provided in an electron column (not illustrated) below the electron gun 100.

The electron source 103 is directly or indirectly supported inside the vacuum chamber 101 by the electron source support member 106. Here, the meaning expressed as “directly or indirectly supported” will be described. The electron source support member 106 is made of metal such as stainless steel (SUS) and has a columnar shape. It is conceivable to support the electron source 103 by bonding the electron source 103 to a lower end of the electron source support member 106. In such a form, it can be said that the electron source support member 106 directly supports the electron source 103.

As another method, the electron source support member 106 may be made of an insulator, the electron source support member 106 may further include a metal wire, and the electron source 103 may be supported by bonding the metal wire and the electron source 103. In this form, it can be said that the electron source support member 106 indirectly supports the electron source 103 via the metal wire. In an example in FIG. 1, the electron source support member 106 is illustrated to directly support the electron source 103, but another member provided with the electron source support member 106 may support the electron source 103 as described above.

The moving mechanism 107 moves the electron source support member 106 in XYZ directions. Here, “moves in XYZ directions” means moving by a desired distance in each of the three directions, that is, the X direction, the Y direction, and the Z direction. In FIG. 1, the electron source support member 106 is held in the vacuum chamber 101 via the moving mechanism 107, but the electron source support member 106 may be directly held in the vacuum chamber 101.

Here, the moving mechanism 107 has a first function of moving the electron source support member 106 in the XYZ directions, and separately from the first function, a second function of moving the electron source support member 106 from an outside of the vacuum chamber 101. Here, “outside of the vacuum chamber 101” means an environment at ambient pressure that is not in contact with the high vacuum space 102.

By providing the second function described above, it is possible to counteract a force caused by an air pressure difference between the outside of the vacuum chamber 101 and the first function. Accordingly, when the electron source support member 106 is moved to a desired position in the XYZ directions by the first function, precise positioning can be achieved.

### Second Embodiment

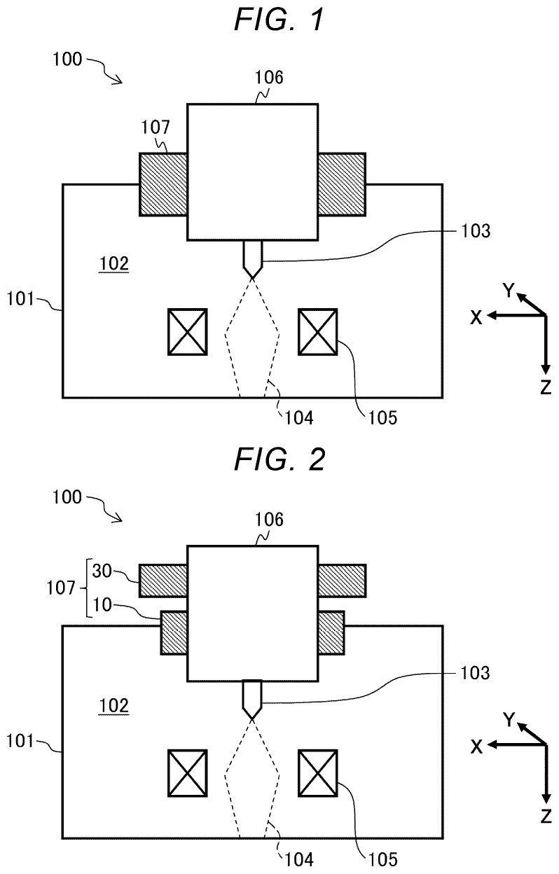

FIG. 2 is a schematic diagram of the electron gun 100 according to a second embodiment.

In the second embodiment, the moving mechanism 107 includes a first moving device 10 and a second moving device 30. The first moving device 10 achieves the first function of moving the electron source support member 106 in the XYZ directions. The second moving device 30 achieves the second function of moving the electron source support member 106 in the Z direction, separately from the first moving device 10.

Here, the second moving device 30 is disposed outside the vacuum chamber 101. The second moving device 30 applies, to the electron source support member 106, a force that counteracts the force caused by the air pressure difference, so that the first moving device 10 is free from the force generated by the air pressure difference. Then, the first moving device 10 moves the electron source support member 106 to a desired position in the XYZ directions. Accordingly, when the electron source support member 106 is moved by the first moving device 10, precise positioning can be achieved. A configuration of the second embodiment other than that described above is similar to that of the first embodiment.

### Third Embodiment

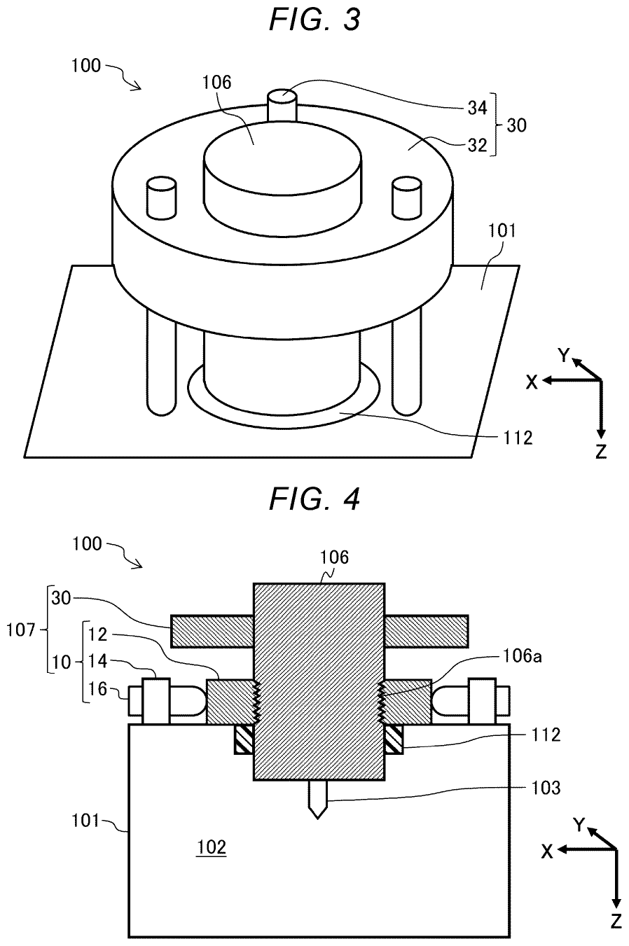

FIG. 3 is a schematic perspective view of main parts of the electron gun 100 according to a third embodiment. That is, FIG. 3 illustrates the second moving device 30, a part of an upper surface of the vacuum chamber 101, and a part of the electron source support member 106 in the electron gun 100. The third embodiment is provided with a specific configuration of the second moving device 30 in the second embodiment. As illustrated in FIG. 3, the second moving device 30 is disposed outside the vacuum chamber 101, that is, above the vacuum chamber 101.

The electron source support member 106 and the vacuum chamber 101 are coupled via a coupling member 112. The coupling member 112 is a member that allows the electron source support member 106 to move in the XYZ directions while maintaining a vacuum state of the vacuum chamber 101, and can be implemented using, for example, a bellows.

In the illustrated example, the second moving device 30 includes a cylindrical portion 32 and three set screws 34. The cylindrical portion 32 is formed in a cylindrical shape, through holes (with no reference sign) are formed along the Z direction at three equal intervals in a circumferential direction, and female threads are threaded into these through holes (not illustrated).

An inner circumferential surface of the cylindrical portion 32 is in contact with the columnar electron source support member 106 and is fixed to the electron source support member 106. Each of the set screws 34 is formed in a substantially columnar shape, and a male thread (not illustrated) is threaded on the outer circumferential surface thereof. The set screw 34 is inserted while being screwed into the through hole formed in the cylindrical portion 32. A lower end of the set screw 34 is in contact with the upper surface of the vacuum chamber 101.

When the set screw 34 is turned with a lower end portion of the set screw 34 in contact with the upper surface of the vacuum chamber 101, a force in a negative direction of a Z-axis is applied to the electron source support member 106 through the cylindrical portion 32. By turning the set screw 34 an appropriate amount, a force due to the atmospheric pressure applied to the electron source support member 106 is counteracted. Accordingly, the first moving device 10 is freed (see FIG. 2), and then precise positioning of the electron source support member 106 can be performed.

The second moving device 30 may be provided with a member such as a screw or a block (not illustrated) other than the set screw 34. That is, it is also possible to make the second moving device 30 movable by these members and counteract the force due to the atmospheric pressure applied to the first moving device 10 (see FIG. 2). For example, a male thread may be threaded on a circumferential surface of the electron source support member 106, a female thread may be threaded on an inner circumferential surface of the cylindrical portion 32, and both may be screwed together. Accordingly, by rotating the cylindrical portion 32, a force in the negative direction of the Z-axis can be applied to the electron source support member 106, and the force due to the atmospheric pressure applied to the first moving device 10 can be counteracted.

### Fourth Embodiment

FIG. 4 is a schematic cross-sectional view of main parts of the electron gun 100 according to a fourth embodiment. That is, FIG. 4 mainly illustrates the first moving device 10 and its peripheral portion in the electron gun 100.

The first moving device 10 illustrated in FIG. 4 includes a rotating member 12, protrusions 14, and set screws 16. The electron source support member 106 has a male thread portion 106a formed by threading a male thread on the circumferential surface thereof. The rotating member 12 is formed in, for example, a cylindrical shape, and a female thread (no reference sign) is threaded an inner circumferential surface thereof. The female thread is screwed to the male thread portion 106a of the electron source support member 106, so that the rotating member 12 is mounted on the electron source support member 106.

The protrusions 14 are provided at four equal intervals in the circumferential direction around the rotating member 12, that is, at positive and negative positions in the X direction and positive and negative positions in the Y direction. In FIG. 4, only two protrusions 14 provided at the positive and negative positions in the X direction are illustrated. Each of the protrusion 14 protrudes upward from the upper surface of vacuum chamber 101. A through hole (not illustrated) extending from an outer peripheral side to an inner peripheral side of the protrusion 14 is formed in the protrusion 14, and female threads are threaded into these through holes.

A total of four set screws 16 are provided and screwed into through holes (not illustrated) formed in the respective protrusions 14. In FIG. 4, only two set screws 16 are illustrated. When the set screw 16 is turned, a tip portion of the set screw 16 is moved in a direction of pushing in the rotating member 12, thereby moving the electron source support member 106. For example, when the two set screws 16 illustrated in FIG. 4 are turned, the electron source support member 106 is moved in the X direction via the rotating member 12.

Here, procedures for positioning the electron source support member 106 using the first moving device 10 and the second moving device 30 will be described.
Procedure #1: First, in the first moving device 10, the set screw 16 is loosened so that a force from the set screw 16 is not applied to the rotating member 12. Then, the rotating member 12 is rotated in a release direction to separate the rotating member 12 from the upper surface of the vacuum chamber 101.
Procedure #2: Next, coarse adjustment of a Z-direction position of the electron source support member 106 is performed using the second moving device 30. When the electron source support member 106 is moved in the Z direction by the second moving device 30, the rotating member 12 also moves along with the electron source support member 106. In the coarse adjustment, the position of the electron source support member 106 in the Z direction may be slightly lower than an ideal position.
Procedure #3: Next, in the first moving device 10, when the rotating member 12 is rotated in a tightening direction, the rotating member 12 eventually comes into contact with the upper surface of the vacuum chamber 101. In this contact state, when the rotating member 12 is further rotated in the tightening direction, the electron source support member 106 gradually moves upward.

Conversely, when the rotating member 12 is rotated in the release direction with the rotating member 12 in contact with the vacuum chamber 101, the electron source support member 106 gradually moves downward. Accordingly, fine adjustment of the Z-direction position of the electron source support member 106 is performed by operating the rotating member 12. As described above, the force due to the atmospheric pressure applied to the electron source support member 106 is almost counteracted by the second moving device 30 (for example, the one in FIG. 3). Therefore, a user can rotate the rotating member 12 with a relatively weak force. Accordingly, the user can operate the rotating member 12 to perform precise position adjustment in the Z direction with respect to the electron source support member 106.
Procedure #4: Next, positions of the electron source support member 106 in the X direction and the Y direction are adjusted by rotating the four set screws 16.

Thus, according to the present embodiment, after making the first moving device 10 free from the atmospheric pressure by the second moving device 30, the user can use the first moving device 10 to perform fine adjustment of the Z-direction position of the electron source support member 106 by operating the rotating member 12. According to the present embodiment, since it is not necessary to include a piezoelectric element or the like inside the vacuum chamber 101, it is possible to implement the electron gun 100 capable of baking the vacuum chamber 101 at a high temperature and moving the electron source 103 in the Z direction as well. A configuration of the fourth embodiment other than that described above is similar to any of the first to third embodiments.

### Fifth Embodiment

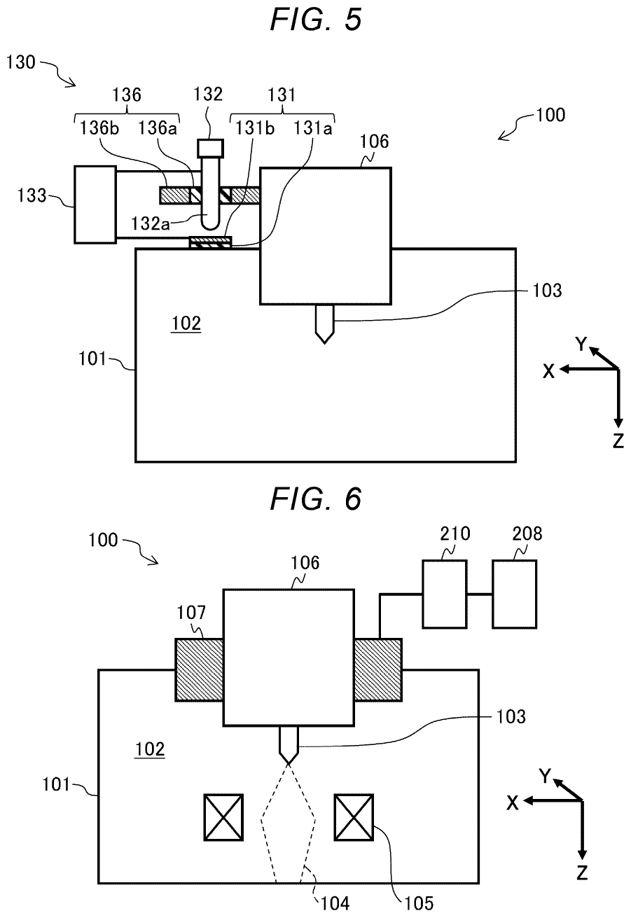

FIG. 5 is a schematic diagram of the electron gun 100 according to a fifth embodiment.

In the fifth embodiment, a position specifying unit 130 is provided in any of the second to fourth embodiments. The position specifying unit 130 is a device that specifies a position of the electron source support member 106 in the Z direction adjusted by the first moving device 10 (see FIG. 2). In FIG. 5, the position specifying unit 130 includes a pad portion 131, a micrometer 132, a conduction detection portion 133, and a micrometer support member 136.

The micrometer support member 136 includes an insulating portion 136a and a mounting portion 136b. The mounting portion 136b is mounted on the micrometer support member 136 and supports the insulating portion 136a. The insulating portion 136a is formed by forming an insulating member such as resin in an annular shape, and has a female thread (not illustrated) threaded on an inner circumferential surface thereof.

The micrometer 132 includes a male thread portion 132a formed in a male thread shape, and the male thread portion 132a is screwed into the insulating portion 136a. Accordingly, a tip portion of the male thread portion 132a of the micrometer 132 protrudes downward from the micrometer support member 136. The micrometer 132 measures a protruding length of the male thread portion 132a from the micrometer support member 136.

The pad portion 131 is a sheet-shaped member mounted on the upper surface of the vacuum chamber 101, and includes an insulator sheet portion 131a and a conductor sheet portion 131b. The insulator sheet portion 131a is an insulator formed of a resin or the like in a sheet shape, and is mounted on the upper surface of the vacuum chamber 101. The conductor sheet portion 131b is a sheet-shaped conductor bonded to an upper surface of the insulator sheet portion 131a.

The conduction detection portion 133 detects whether the pad portion 131 and the micrometer 132 are in contact with each other. More specifically, the conduction detection portion 133 detects whether the male thread portion 132a of the micrometer 132 and the conductor sheet portion 131b of the pad portion 131 are electrically connected.

Here, a method of using the position specifying unit 130 will be described. First, the micrometer 132 is operated so that the protruding length of the male thread portion 132a from the micrometer support member 136 becomes a length corresponding to a desired Z-direction position of the electron source support member 106. Next, the electron source support member 106 is moved by the first moving device 10 (see FIG. 2). Then, the conduction detection portion 133 detects that the pad portion 131 and the micrometer 132 are in contact with each other at an appropriate movement amount. At this time, the Z-direction position of the electron source support member 106 may be fixed. Thus, by providing the position specifying unit 130, it is possible to move the electron source support member 106 while quantitatively detecting the position of the electron source support member 106.

### Sixth Embodiment

FIG. 6 is a schematic diagram of the electron gun 100 according to a sixth embodiment.

Similarly to the first embodiment (see FIG. 1), the electron gun 100 according to the present embodiment includes the vacuum chamber 101, the electron source 103, the condenser coil 105, the electron source support member 106, and the moving mechanism 107. Further, the electron gun 100 according to the present embodiment includes a drive unit 210 and a controller 208.

The controller 208 outputs a position command signal for commanding a position of the electron source support member 106. The drive unit 210 drives the moving mechanism 107 based on the position command signal. For example, when the second moving device 30 illustrated in FIG. 3 is adopted, the controller 208 and the drive unit 210 can turn the set screw 34 by a motor (not illustrated).

When the first moving device 10 illustrated in FIG. 4 is adopted, the controller 208 and the drive unit 210 can rotate the rotating member 12 and the protrusion 14 by a motor (not illustrated). Instead of the rotating member 12 and the set screw 16, an appropriate actuator (not illustrated) is provided, and the controller 208 and the drive unit 210 can move the electron source support member 106 by driving the actuator. Thus, by providing the controller 208 and the drive unit 210, it is not necessary for a user to directly adjust the position of the electron source support member 106, and an effect such as reduction in maintenance time can be obtained.

In FIG. 4, when the motor or the actuator is applied instead of the rotating member 12 and the set screw 16, it is obvious that a temperature restriction at the time of baking described as a problem at the beginning does not cause a problem in the present embodiment. This is because the moving mechanism 107 in the present disclosure can adjust the position of the electron source support member 106 from an outside of the vacuum chamber 101.

At a disposition place of the moving mechanism 107 outside the vacuum chamber 101, a temperature does not rise as much as inside of the vacuum chamber 101, and a motor or an actuator can be disposed. If necessary, the motor and the actuator may be configured to be detached during baking.

When control by an actuator or a motor is adopted, linked control may be adopted such that the electron source support member 106 moves also in the Z direction while automatically moving in the X and Y directions.

### Seventh Embodiment

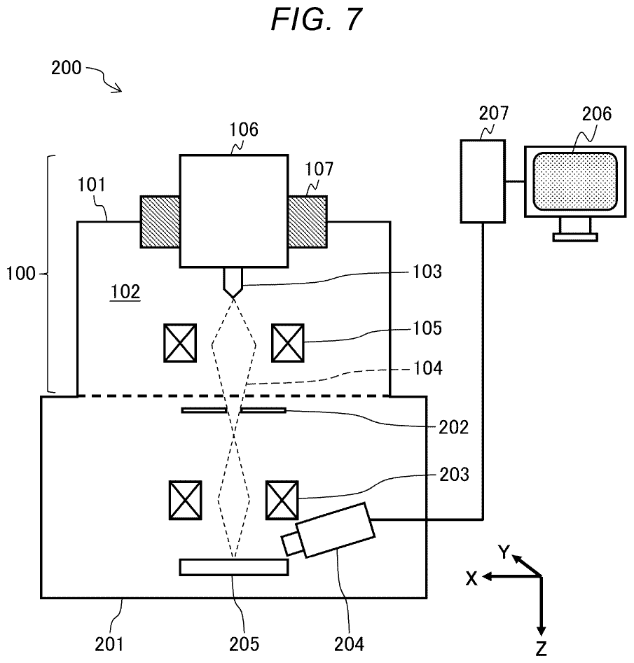

FIG. 7 is a schematic diagram of a charged particle beam apparatus 200 according to a seventh embodiment. As in the first to sixth embodiments, the charged particle beam apparatus 200 is applicable to, for example, an SEM.

The charged particle beam apparatus 200 includes the electron gun 100, a vacuum chamber 201, an aperture 202, a condenser coil 203, and a detector 204. A sample 205 is placed at a predetermined position in the vacuum chamber 201. A configuration of the electron gun 100 is similar as that of the first embodiment. The high vacuum space 102 of the vacuum chamber 101 communicates with an internal space of the vacuum chamber 201.

The electron beam 104 emitted by the electron gun 100 is guided to the downstream vacuum chamber 201 and focused to irradiate the sample 205. At this time, the electron beam 104 is focused by the condenser coil 105, and then clipped by the aperture 202, further focused by the condenser coil 203, and is used to irradiate the sample 205.

What is described in the present embodiment is an example of an optical system that irradiates a sample with a focused charged particle beam, and does not limit the present disclosure. For example, the charged particle beam apparatus 200 includes an electrode instead of the condenser coil 203, and may focus the electron beam 104 by an electric field, or may include both the condenser coil 203 and the electrode.

Regarding members for focusing the electron beam 104, any number of one or more may be provided. Two or more apertures 202 may be provided. In addition, as in the other embodiments described above, the condenser coil 105 and the aperture 202 may be provided either inside or outside the electron gun 100.

The focused electron beam 104 is used to irradiate the sample 205, and the detector 204 detects a signal generated by the irradiation of the electron beam. Here, various signals may be detected. In the SEM according to the present embodiment, typically, secondary electrons emitted from the sample are detected, but in a case of a transmission electron microscope (TEM), it is also conceivable to detect transmitted electrons that interact with the sample, or depending on an application, electromagnetic waves such as X-rays or cathodoluminescence.

In FIG. 7, the detector 204 detects the secondary electrons emitted from the sample 205 having a component in the negative direction of the Z-axis. However, as described above, various detection targets are conceivable, and the scope of the present disclosure is not limited by the configuration of FIG. 7. The signal detected by the detector 204 is taken into a computer system 207, processed, and then displayed on a GUI device 206 (user interface device) having a graphical user interface (GUI) function.

In the present embodiment, the position of the electron source support member 106 can be adjusted using the moving mechanism 107 while referring to one or more signals displayed on the GUI device 206. Examples of the signal to be displayed on the GUI device 206 include an image obtained by irradiation with the electron beam 104 and a current value obtained by collecting the electron beam 104.

As position adjustment of the electron source support member 106 while looking at the GUI device 206, for example, the following method can be considered. In an adjustment stage of the charged particle beam apparatus 200 after the electron gun 100 is mounted, it is conceivable that axes of the electron source 103 and the aperture 202 are not aligned due to an assembly tolerance. Therefore, these axes are to be aligned. First, adjustment is performed in advance so that an axis of a member below the aperture 202 coincides with a screen center on the GUI device 206.

Next, without passing current through the condenser coil 105, 203, the electron beam emitted from the sample 205 is displayed on the GUI device 206. When the axes of the electron source 103 and the aperture 202 are not aligned with each other, an image of the electron beam emitted from the sample 205 is displayed at a portion deviated from the screen center of the GUI device 206. Therefore, the electron source support member 106 is moved using the XY moving mechanism of the moving mechanism 107 so that the electron image is positioned at the screen center of the GUI device 206. Accordingly, it is possible to align the axis of the electron source 103 with the axis of the aperture 202.

An adjustment method using a moving function of the moving mechanism 107 in the Z direction includes, for example, the following. First, a current value of the condenser coil 105, 203 is adjusted so that the electron beam emitted from a desired Z coordinate of the electron source 103 is focused on the sample 205. Here, if the Z coordinate of the electron source 103 is not at a desired position, an SEM image displayed on the GUI device 206 becomes blurred. In this case, the Z coordinate of the electron source 103 may be adjusted so that the SEM image is in focus by using the moving function of the moving mechanism 107 in the Z direction. Accordingly, the Z coordinate of the electron source 103 can be adjusted to a desired position.

### Eighth Embodiment

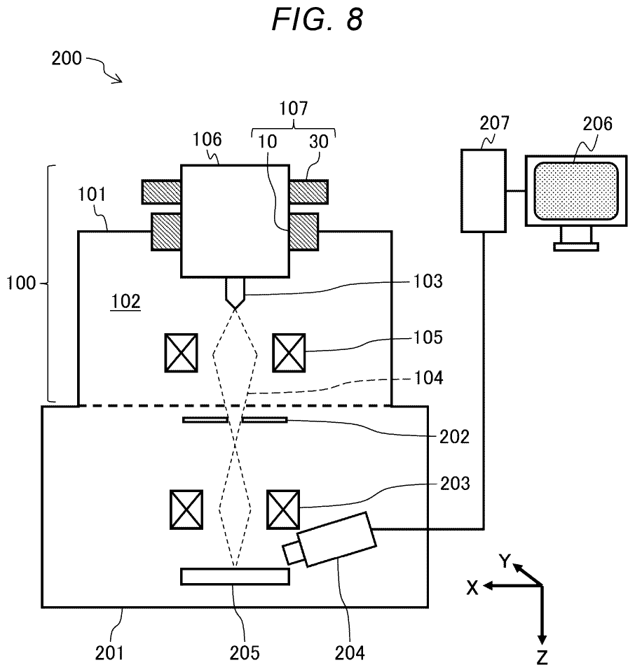

FIG. 8 is a schematic diagram of the charged particle beam apparatus 200 according to an eighth embodiment.

In the present embodiment, the moving mechanism 107 is implemented similarly to that of the second embodiment (see FIG. 2). That is, the moving mechanism 107 includes the first moving device 10 and the second moving device 30 that moves the electron source support member 106 in the direction from an outside of the vacuum chamber 101. A configuration of the present embodiment other than that described above is similar to that of the seventh embodiment (see FIG. 7). According to the present embodiment, similarly to the second embodiment described above, it is possible to implement the electron gun 100 in which a baking temperature is not restricted and the electron source support member 106 can be adjusted in three directions, that is, XYZ.

### Ninth Embodiment

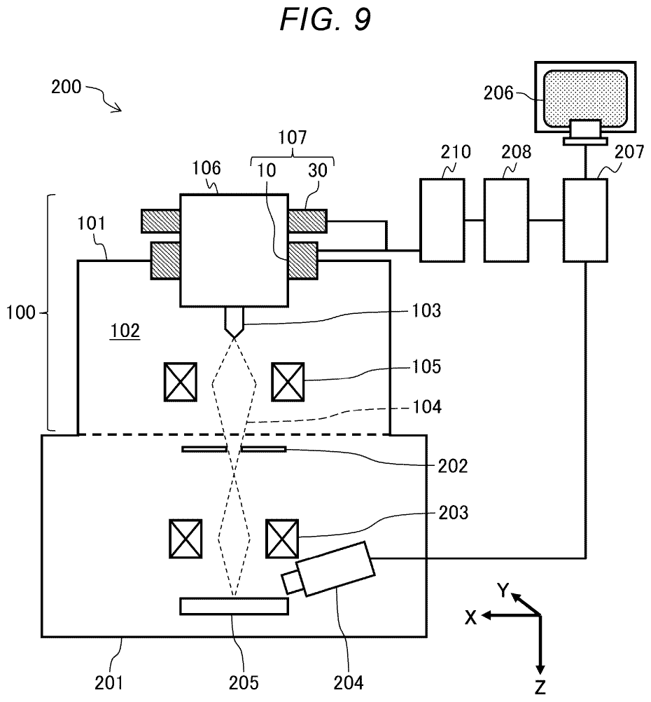

FIG. 9 is a schematic diagram of the charged particle beam apparatus 200 according to a ninth embodiment.

In the present embodiment, the charged particle beam apparatus 200 further includes the controller 208 and the drive unit 210 in addition to a similar configuration as that of the eighth embodiment (see FIG. 8). As in the sixth embodiment (see FIG. 6), the controller 208 outputs a position command signal for commanding a position of the electron source support member 106. The drive unit 210 drives the moving mechanism 107 based on the position command signal.

In the present embodiment, a user can remotely operate the moving mechanism 107 via the controller 208 and the drive unit 210. Accordingly, the position of the electron source support member 106 can be adjusted such that various parameters are optimized while referring to an SEM image displayed on the GUI device 206. The position adjustment of the electron source support member 106 is not limited to a manual operation by the user, and the position adjustment of the electron source support member 106 may be automatically performed by the computer system 207.

### Configuration of Computer

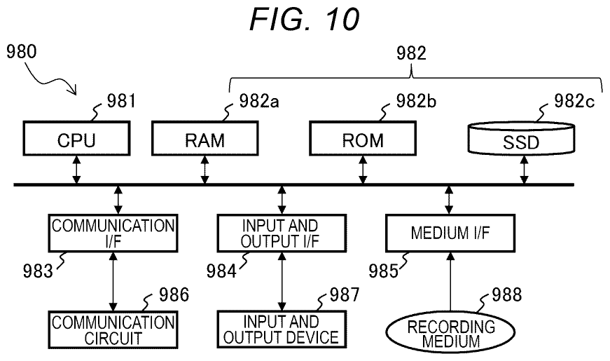

FIG. 10 is a block diagram of a computer 980. Each of the GUI device 206, the computer system 207, and the controller 208 illustrated in FIGS. 6 to 9 includes one or more computers 980 illustrated in FIG. 10.

In FIG. 10, the computer 980 includes a CPU 981, a storage unit 982, a communication I/F (interface) 983, an input and output I/F 984, and a medium I/F 985.

The storage unit 982 includes a RAM 982a, a ROM 982b, and a solid state drive (SSD) 982c. The communication I/F 983 is connected to a communication circuit 986. The input and output I/F 984 is connected to an input and output device 987. The medium I/F 985 reads and writes data from and to a recording medium 988. The ROM 982b stores an initial program loader (IPL) and the like executed by the CPU. The SSD 982c stores a control program, various kinds of data, and the like. The CPU 981 implements various functions by executing the control program and the like read from the SSD 982c to the RAM 982a.

### Modification

The present disclosure is not limited to the above-described embodiments, and various modifications are possible. The embodiment described above has been exemplified to describe the present disclosure in an easy-to-understand manner, and the present disclosure is not necessarily limited to including all the described configurations. A part of a configuration of a certain embodiment can be replaced with a configuration of another embodiment, and a configuration of another embodiment can be added to a configuration of a certain embodiment. A part of a configuration of each embodiment can be deleted, or can be added or replaced by another configuration. Control lines and information lines illustrated in the drawings are considered to be necessary for description, and not all control lines and information lines in a product are necessarily illustrated. Actually, almost all configurations may be considered to be connected.

Modifications that can be made to the above embodiment are as follows, for example.

(1) In the above embodiments, a disposition position and the number of the condenser coil 105, 203 may be appropriately changed, and the condenser coil 105, 203 may be replaced with an electrode as described above.

(2) Since hardware of the GUI device 206, the computer system 207, and the controller 208 in the embodiments can be achieved by a general computer, a program or the like for executing various kinds of processing described above may be stored in a storage medium (computer-readable recording medium in which a program is recorded) or may be distributed via a transmission line.

(3) Although various kinds of processing executed by the GUI device 206, the computer system 207, and the controller 208 in the above embodiments are described as software processing using a program in the embodiment, some or all the processing may be replaced with hardware processing using an application specific integrated circuit (ASIC), a field programmable gate array (FPGA), or the like.

(4) Various kinds of processing executed by the GUI device 206, the computer system 207, and the controller 208 in the above embodiments may be executed by a server computer via a network (not illustrated), and various kinds of data stored in the above embodiments may also be stored in the server computer.

### Effects of Embodiment

As described above, according to the above-described embodiment, the moving mechanism 107 in the charged particle beam apparatus (100, 200) has the first function of moving the charged particle source support member (106) in the X direction, the Y direction, and the Z direction, and the second function of moving the charged particle source support member (106) in the Z direction from the outside of the vacuum chamber 101, separately from the first function. Accordingly, since the force in the Z direction applied to the charged particle source support member (106) can be carried by the first function and the second function, it is possible to perform highly accurate position adjustment by both functions, and it is possible to achieve appropriate position adjustment of the charged particle source.

It is more preferable that the moving mechanism 107 includes the first moving device 10 having the first function and the second moving device 30 having the second function, and the second moving device 30 is disposed outside the vacuum chamber 101. Thus, by disposing the second moving device 30 outside the vacuum chamber 101, the second moving device 30 can be easily handled, and a temperature of the second moving device 30 can also be reduced.

It is more preferable that the charged particle source support member (106) has a columnar shape with the male thread portion 106a formed by threading a male thread on an outer circumferential surface, and the first moving device 10 includes the rotating member 12 that has the female thread portion screwed to the male thread portion 106a and moves the charged particle source support member (106) in the Z direction when rotated. Accordingly, the charged particle source support member (106) can be moved by rotating the rotating member 12.

It is more preferable to further include the position specifying unit 130 configured to specify the position of the charged particle source support member (106) adjusted by the first moving device 10. Accordingly, it is possible to move the charged particle source support member (106) while quantitatively detecting the position of the charged particle source support member (106).

It is more preferable that the charged particle beam apparatus (100, 200) further includes: the controller 208 configured to output a position command signal for commanding the position of the charged particle source support member (106); and the drive unit 210 configured to drive the moving mechanism 107 based on the position command signal. Accordingly, the user can remotely operate the moving mechanism 107.

From another viewpoint, the charged particle beam apparatus 200 in the seventh to the ninth embodiments includes one or more detectors 204 that detect a charged particle transmitted through the sample 205, a charged particle emitted from the sample 205, or an electromagnetic wave emitted from the sample 205, and the user interface device (206), and the user interface device (206) has a function of displaying an output signal when the detector 204 detects the charged particle or the electromagnetic wave, and a function of adjusting a position of the charged particle source (103) by the moving mechanism 107 based on an operation of the user. Accordingly, the user can adjust the position of the charged particle source (103) by the moving mechanism 107 while referring to various signals displayed on the user interface device (206).

What is claimed is:

1. A charged particle beam apparatus comprising:
a charged particle gun configured to perform irradiation with a charged particle beam; and
a focusing lens, wherein
the focusing lens focuses charged particles by an electric field or a magnetic field and irradiates a sample with the focused charged particles,
the charged particle gun includes
a charged particle source configured to emit the charged particles,
a vacuum chamber that surrounds the charged particle source,
a charged particle source support member that directly or indirectly supports the charged particle source, and
a moving mechanism configured to move the charged particle source support member, and
the moving mechanism has
a first function of, with a travel direction of the charged particles emitted from the charged particle source defined as a Z direction, a direction perpendicular to the Z direction defined as an X direction, and a direction perpendicular to the Z direction and the X direction defined as a Y direction, moving the charged particle source support member in the X direction, the Y direction, and the Z direction, and
a second function of moving the charged particle source support member in the Z direction from an outside of the vacuum chamber, separately from the first function.

2. The charged particle beam apparatus according to claim 1, wherein
the moving mechanism includes a first moving device having the first function and a second moving device having the second function, and
the second moving device is disposed outside the vacuum chamber.

3. The charged particle beam apparatus according to claim 2, wherein
the charged particle source support member has a columnar shape with a male thread portion formed by threading a male thread on an outer circumferential surface, and
the first moving device includes a rotating member that has a female thread portion screwed to the male thread portion and moves the charged particle source support member in the Z direction when rotated.

4. The charged particle beam apparatus according to claim 2, further comprising:
a position specifying unit configured to specify a position of the charged particle source support member adjusted by the first moving device.

5. The charged particle beam apparatus according to claim 3, further comprising:
a position specifying unit configured to specify a position of the charged particle source support member adjusted by the first moving device.

6. The charged particle beam apparatus according to claim 4, further comprising:
a controller configured to output a position command signal for commanding a position of the charged particle source support member; and
a drive unit configured to drive the moving mechanism based on the position command signal.

7. The charged particle beam apparatus according to claim 5, further comprising:
a controller configured to output a position command signal for commanding a position of the charged particle source support member; and
a drive unit configured to drive the moving mechanism based on the position command signal.

8. A charged particle beam apparatus for irradiating a sample with a focused charged particle beam, the charged particle beam apparatus comprising:
a charged particle source configured to emit a charged particle;
a vacuum chamber that surrounds the charged particle source;
a charged particle source support member that directly or indirectly supports the charged particle source;
a moving mechanism configured to move the charged particle source support member;
one or more detectors configured to detect a charged particle transmitted through the sample, a charged particle emitted from the sample, or an electromagnetic wave emitted from the sample; and
a user interface device, wherein
the user interface device has
a function of displaying an output signal when the detector detects the charged particle or the electromagnetic wave, and
a function of adjusting a position of the charged particle source by the moving mechanism based on an operation of a user.

9. The charged particle beam apparatus according to claim 8, wherein
the moving mechanism has
a first function of, with a travel direction of the charged particle emitted from the charged particle source defined as a Z direction, a direction perpendicular to the Z direction defined as an X direction, and a direction perpendicular to the Z direction and the X direction defined as a Y direction, moving the charged particle source support member in the X direction, the Y direction, and the Z direction, and
a second function of moving the charged particle source support member in the Z direction from an outside of the vacuum chamber, separately from the first function.

10. The charged particle beam apparatus according to claim 9, wherein
the moving mechanism includes a first moving device having the first function and a second moving device having the second function, and
the second moving device is disposed outside the vacuum chamber.

11. The charged particle beam apparatus according to claim 8, further comprising:
a controller configured to output a position command signal for commanding a position of the charged particle source support member; and
a drive unit configured to drive the moving mechanism based on the position command signal.

12. The charged particle beam apparatus according to claim 9, further comprising:
a controller configured to output a position command signal for commanding a position of the charged particle source support member; and
a drive unit configured to drive the moving mechanism based on the position command signal.

13. The charged particle beam apparatus according to claim 10, further comprising:
a controller configured to output a position command signal for commanding a position of the charged particle source support member; and
a drive unit configured to drive the moving mechanism based on the position command signal.

14. A charged particle gun comprising:
a charged particle source configured to emit a charged particle;
a vacuum chamber that surrounds the charged particle source;
a charged particle source support member that directly or indirectly supports the charged particle source; and
a moving mechanism configured to move the charged particle source support member, wherein
the charged particle source support member has a columnar shape with a male thread portion formed by threading a male thread on an outer circumferential surface, and
the moving mechanism includes a rotating member that has a female thread portion screwed to the male thread portion and moves the charged particle source support member in a Z direction that is a travel direction of the charged particle emitted from the charged particle source when rotated.

15. The charged particle gun according to claim 14, wherein
the moving mechanism is configured to move the charged particle source support member in the Z direction from an outside of the vacuum chamber.
